(19) United States
(12) Patent Application Publication
(10) Pub. No.: US 2025/0239494 A1
(43) Pub. Date: Jul. 24, 2025

(54) METHOD TO OBTAIN INFORMATION TO CONTROL A MANUFACTURING PROCESS FOR A STACKED SEMICONDUCTOR DEVICE AND DETECTION SYSTEM USING SUCH METHOD

(71) Applicant: Carl Zeiss SMT GmbH, Oberkochen (DE)

(72) Inventors: Christian Lutzweiler, München (DE); Stratis Tzoumas, Baierbrunn (DE); Johannes Ruoff, Cupertino, CA (US)

(21) Appl. No.: 19/175,228

(22) Filed: Apr. 10, 2025

Related U.S. Application Data
(63) Continuation-in-part of application No. PCT/EP2023/076825, filed on Sep. 28, 2023.

(30) Foreign Application Priority Data
Oct. 14, 2022 (GR) 20220100852
Nov. 14, 2022 (DE) 102022212027.2

(51) Int. Cl. H01L 21/66; G01N 23/046; G01N 23/18; G03F 7/00

(52) U.S. Cl. CPC H01L 22/12; G01N 23/046; G01N 23/18; G03F 7/70655; G03F 7/706837; G03F 7/706841; G03F 7/706845

(57) ABSTRACT

In a method to obtain information to control a manufacturing process for a stacked semiconductor device including several semiconductor layers requiring electrically interconnection, sample data of a semiconductor device sample to be inspected are provided. An X-ray imaging scan of the sample obtaining respective X-ray imaging data is performed. Sample detail information of sample details of the sample are gathered from the X-ray imaging data which are vital for the manufacturing process. Multiple Regions of Interest (ROIs) are identified from the gathered sample detail information by processing data resulting from an ROI identification model, such ROI identification model being previously trained in a machine learning process. Metrology data are extracted from the identified ROIs by processing data resulting from a metrology model, such metrology model being previously trained in a machine learning process. With such method, a process time to obtain the required information to control the manufacturing process can be reduced.

### CROSS-REFERENCE TO RELATED APPLICATIONS

This application is a continuation-in-part of and claims benefit under 35 U.S.C. § 120 from PCT Application PCT/EP2023/076825, filed on Sep. 28, 2023, which claims priority from Greek Application 2022 0100 852, filed on Oct. 14, 2022, and German Application 10 2022 212 027.2, filed on Nov. 14, 2022. The entire contents of each of these earlier applications are incorporated herein by reference.

### TECHNICAL FIELD

The invention refers to a method to obtain information to control a manufacturing process for a stacked semiconductor device including several semiconductor layers requiring electrical interconnection and further refers to a detection system using such method.

### BACKGROUND

A detection system for X-ray inspection of an object is known from U.S. Pat. No. 9,129,715 B2. Other such detection systems are known from U.S. Pat. No. 7,057,187 B1 and from DE 10 2018 209 570 A1. Further, for object imaging, X-ray inspection microscopes (uCTs) and optical assisted X-ray microscopes (XRM) are known in the art. For uCTs several tomosynthesis geometries are known, wherein detectors are placed at different positions with respect to a central inspection axis. A detector and/or the sample may be moved. In that respect, it is referred to U.S. Pat. No. 7,130,375 B1 and to US 7,057,187 B1. US 2021/0073976 A1 discloses wafer inspection methods and systems. EP 1 126 477 A2 discloses a method to inspect structures on a semiconductor substrate.

### SUMMARY

It is an aspect of the invention to reduce a process time to obtain the required information to control the manufacturing process.

This aspect is met via a method according to the features of claim 1.

Current generation System on a Chip incarnations (SoC) and high performance memory systems (e.g. HBM) are composed from multiple individual chiplets. After (front-end) fabrication, these chiplets are wired to stacked semiconductor devices including several semiconductor layers in the packaging phase by so-called interconnects (IC). As the required interconnect density substantially increases (e.g. to fulfill higher bandwidth requirements), the interconnect pitch and size has to be decreased accordingly, potentially also necessitating different wiring technologies such as transitioning from Sn-based soldering to Cu—Cu-processes.

The higher complexity of such high density interconnects transforms the packaging process from a stable, easy to control manufacturing process with highest yields, where it suffices to inspect a few control samples only after ramp-up, to a substantially more involved process with lower yields, unless closely monitored even after ramp-up. Consequently, an in-line quality control process for interconnects is needed to detect process drifts, or other structural flaws in the contact that would preclude proper functionality or lower the final yield.

Metrics indicative of the manufacturing process issues could comprise, but are not limited to:
Width and height of the solder mass,
radius and height of the contact pads,
relative alignment of the top and bottom pads,
pitch between adjacent contacts,
extrusion of the solder mass with respect to pad areas,
voids or cracks in the solder mass,
electrical shorts between adjacent contacts,
voids or cracks in the pad and TSV material (through-silicon vias).

A suitable process control workflow should meet the following requirements:
Adequate sensitivity with respect to the metrics of interest,
sufficient spatial resolution,
high throughput to inspect sufficiently large areas in multiple/all samples,
handling of full wafer samples (before dicing),
non-destructive imaging,
automated operation without user involvement in regular processing,
suitable, matched combination of measurement hardware and process and analysis software,
volumetric imaging capabilities (several 100 μm thickness/deep within the sample).

It has been found that training of an ROI identification model and also training of a metrology model helps to facilitate obtaining control information for the manufacturing process.

Such training of the respective model may be performed during an analytics ramp-up phase of the manufacturing process.

Information with a quality to improve the manufacturing process then can be obtained with less data acquisition effort. On the one hand, this may reduce requirements of a detection system used to perform the X-ray imaging scan or reduces requirements for an X-ray imaging scan performance emulation. Such emulation may be used for a model training. On the other hand, with a given imaging scan effort, higher quality data may be obtained.

The sample data may be provided via a real physical sample or via CAD data of the sample, in particular CAD data of the respective semiconductor layers. In such latter case of a provision of CAD data of the sample, the performed X-ray imaging scan may be the product of an emulation.

Volumes reconstructed from data obtained via an X-ray inspection tool by established methods are susceptible to artifacts (stemming from restricted maximum scanning angle, limited number of projections, noise). In particular, there is a clear trade-off between throughput (number and range of projections, photon integration time), hardware limitations and cost (beam opening angle, working distances) and achieved reconstruction quality/artifacts. Ultimately, there is a trade-off between throughput and accuracy of the retrieved metrology parameters using such established method. Such trade-off is avoided using the method to obtain information to control the manufacturing process with the help of a pre-trained ROI identification model and further with the help of a pre-trained metrology model.

During a typical X-ray imaging scan, an area of the sample is imaged onto a detection field wherein a detection array having at least 1000×1000 pixels is arranged. The detection array may have 2000×2000 pixels. During a typical imaging scan, more than 100 images corresponding to different orientations of the sample are generated. Such number of images corresponding to different sample orientations may be in the range between 10 and 2000, e.g. between 10 and 100 or between 100 and 2000.

During a typical gathering of sample detail information, such pixel volume is converted into typically 1000×1000×1000 voxels. In the ROI identification step, these 10003 voxels are reduced to typically 100 to 10000 ROIs each having typically 5033 50×50 voxels to 100×100×100 voxels, e.g. 64×64×64 voxels.

During the extracting step, from this reduced number of e.g. 643 voxels, typically three metrology parameters, e.g. the three dimensions of a structure within the respective ROI are obtained.

Training of an ROI identification model according to claim 2 uses labelled ROIs which in the machine learning process can be annotated as qualified results. The sample detail information may be gathered via a volume reconstruction of at least a part of the device sample, including at least two adjacent semiconductor layers. The ROI identification may be performed via a neuronal network or via a Hough Forest, which is referenced to later on.

A labelling and a training during the detecting and extracting step may be performed in parallel.

Training of a metrology model according to claim 3 uses comparative data from an accurate gathering mode and from a fast gathering mode. The fast mode data then may result in information to control the manufacturing process, such information being at a same quality level as those previously only obtainable via the accurate sample detail information gathering. The sample detail information may be gathered via a volume reconstruction of at least a part of the device sample including at least two adjacent semiconductor layers. In the fast mode, a fast X-ray imaging scan of the sample may be performed, obtaining respectively rough X-ray imaging data. Alternatively, the rough X-ray imaging data, being the input for the sample detail information gathering, may stem from a software emulation based on reprocessed X-ray data obtained from the accurate X-ray imaging scan.

An artifact correction step according to claim 4 helps to improve the metrology data obtained as the information to control the manufacturing process. Such artifact correction step may be part of a pre-trained metrology model. The volume correction model is an example of the trained metrology model. Applying such volume correction model may considerably reduce structural artifacts stemming from a limited scan range. Such undesired artifacts may, if not corrected, yield a degraded metrological accuracy.

Further, the volume correction model may improve a signal/noise ratio of a volume quality by a factor of e.g. 5, requiring respectively less data acquisition effort.

Applying the volume correction step within the fast mode, an error of an obtained metrology parameter, e.g. of a parameter “bond line” B, may be reduced by, e.g., a factor of 5.

Training a volume correction model according to claim 5 also uses a comparison between information gathered via an accurate mode on the one hand, and a fast mode on the other. The sample detail information may be gathered via a volume reconstruction of at least a part of the device sample, including at least two adjacent semiconductor layers. In the fast mode, a fast X-ray imaging scan of the sample may be performed, obtaining respectively rough X-ray imaging data. Alternatively, the rough X-ray imaging data, being the input of the sample detail information gathering, may stem from a software emulation based on reprocessed X-ray data obtained from the accurate X-ray imaging scan. A generic model may serve as further input for the machine learning training of the volume correction model.

A domain transfer step according to claim 6 may further improve the quality of the trained volume correction model. Such domain transfer step maybe relevant only for emulated data.

Training of the domain adaption model according to claim 7 has advantages which correspond to those already discussed above. The sample detail information may be gathered via a volume reconstruction of at least a part of the device sample, including at least two adjacent semiconductor layers. During the comparison, the respective ROI identification data to be compared are checked with respect to their statistical indistinguishability.

A sample detail information according to claim 8 enables a complete 3-dimensional picture of the sample volume to be inspected.

A sample detail information according to claim 9 may result in less computational or data acquisition effort. The contact identification of contact elements, in particular of interconnects between adjacent semiconductor layers, may be given via Cartesian coordinates of such interconnects. Further, such method may be usable with sample data of lower resolution, reducing the effort to provide the sample data.

Training a metrology model according to claim 10 may avoid in the fast mode the effort of a volume reconstruction step and/or may reduce the amount of sample data to be provided. The sample detail information in the accurate mode may be gathered via a volume reconstruction of at least a part of the device sample including at least two adjacent semiconductor layers. In the fast mode a fast X-ray imaging scan of a sample may be performed obtaining respectively rough X-ray imaging data.

The advantages of a detection system according to claim 11 correspond to those discussed above with reference to the method to obtain the information to control the manufacturing process.

The detection system may include:
High opening angle X-ray source in close proximity to the to be inspected wafer (such opening angle may be, e.g., in the range between 100 degrees and 160 degrees),
matched linear scanning of both wafer and detector in x-and y-direction,
the X-ray inspection tool used might support multiple scanning protocols. The one typically used for in-line inspection is called fast mode.

Such fast mode results in an imaging of full wafers at high throughput, but may result in image degradations such as limited view artifacts and image noise.

An in-line workflow using such detection system comprises at least the following stages:
Selection of samples/large scale ROIs on the sample/chip for inspection,
measurement data acquisition with the X-ray inspection tool in fast mode (two axes linear scan),
reconstruction of volumes from measurement data,
metrology parameter determination from volume,
statistical analysis and generation of actionable information.

A movable object mount according to claim 12 enhances the flexibility of the detection system.

A movable shield stop according to claim 13 further enhances the detection system's flexibility.

Further advantages of the method embodiments according to the claims are given in the below listing:
1. Interconnect ROI identification and interactive training:
   1.1 Utilizing a lightweight detector specifically designed to operate on IC interconnects (computation time and reduced annotation effort compared to Deep Learning).
   1.2 Specifically utilizing a data-driven, trained model as detector (in our case: Hough Forest detector).
   1.3 Interactive user labelling at “ramp-up phase” (to further minimize annotation effort).
   1.4 Ordering of ROI Identification stage before volume correction stage (reduced computation cost at training and inference, reduced volume variation).
2. Volume correction models for contact ROIs:
   2.1 Additional volume correction stage specifically designed to operate on IC interconnects.
   2.2 Specifically utilizing a data-driven, trained model as quality improvement module (e.g. 2.5-D U-Net).
3. Volume correction model training process and corresponding training data acquisition process
   3.1 Training modes:
      3.1.1 General purpose, pre-trained model by ZEISS.
      3.1.2 Full training at customer site during “ramp-up phase”.
      3.1.3 Specialization of an existing model with fewer customer data required at customer site during “ramp-up phase”.
      3.1.4 Continuous online training parallel with in-line inspection from feedback inputs (e.g. from quality control or other, potentially destructive metrology tools).
   3.2 Generating matched pairs fast mode +accurate mode of measurement data for a representative set of samples during “ramp-up phase”.
   3.3 Emulation of fast mode data from accurate mode data (e.g. via synthetic degradation) for a representative set of imaged samples at “ramp-up phase”.
   3.4 Training of specialized models from synthetic data.
      3.4.1 Utilizing CAD files of the to be monitored contacts, parametric distribution of contact variations, and digital twins for both fast mode and accurate mode measurements.
      3.4.2 Potentially utilizing an unmatched, existing set of measurements from another family of contacts to train another “Domain Adaptation” model to reduce the gap of simulated and actual measurements.
      3.4.3 Potentially deriving metrology parameter labels for input sub-volumes directly from CAD geometry.
      3.4.4 Training with mixed simulated and experimental data.
      3.4.5 Pre-training with simulated data, fine-tuning with experimental data.
   3.5 Dedicated sample preparation to facilitate improved sample volume pairs during “ramp-up phase” (e.g. dicing the whole wafers for full angle tomography); or dedicated sample processing for generating sub-volume-metrology-parameter pairs (e.g. destructive modalities after the X-ray inspection tool fast mode imaging).
   3.6 Training of metrology parameter estimation models.
      3.6.1 Operating on reconstructed, degraded sub-volumes.
      3.6.2 Operating directly on crops of measurement data.

### BRIEF DESCRIPTION OF DRAWINGS

Exemplified embodiments of the invention hereinafter are described with reference to the accompanying figures. In these show:

FIG. 1 partly schematically and partly in a perspective depiction a side-view of a detection system capable to perform a method to obtain information to control a manufacturing process for an object embodied as a stacked semiconductor device, the detection system including a detection assembly having an imaging optical arrangement to image an object illuminated by X-rays embodied as a microscope objective including an object mount movable relative to an X-ray source of the detection system;

FIG. 2 in a side view, an example of an object or sample detail which is vital for the manufacturing process which is controlled via the information which is obtained via the respective method, the sample detail being an interconnect between semiconductor layers of the stacked semiconductive device, the interconnect being realized as an Sn-based soldering interconnect, such interconnect shown in a nominal position of two contact pads with a solder mass which also is referred to as a fillet;

FIGS. 3 to 5 further variants of such interconnects with different relative positions of the two contact pads to each other and a resulting solder mass structure in-between to show possible parameter variations during the manufacturing of the interconnect;

FIGS. 6 to 9 the interconnect relative position variants of FIGS. 2 to 5 shown in a perspective view;

FIG. 10 a workflow of a method to obtain information to control a manufacturing process for a stacked semiconductor device including several semiconductor layers requiring electrical interconnection in the form of the interconnect shown in FIGS. 2 to 9, such method being adapted for in-line inspection in production;

FIG. 11 a workflow for a training method to result in a trained Region of Interest (ROI) detection/identification model, the method being adapted for training such ROI detection/identification model during an analytics ramp-up phase, such trained ROI detection model being usable within the method shown in FIG. 10;

FIG. 12 a workflow for a training method resulting in a trained volume correction model usable for the method according to FIG. 10;

FIG. 13 a workflow for a method to obtain information to control a manufacturing process for a stacked semiconductor device which may be used as an alternative to the FIG. 10 method;

FIG. 14 a workflow for training a metrology model resulting in a trained metrology model which is usable within the method of FIG. 13;

FIG. 15 a workflow for training of a volume correction model which may be used as an alternative to the FIG. 12 workflow and which also results in a trained volume correction model;

FIG. 16 a workflow for training of a domain adaption model resulting in a trained domain adaption model usable within the workflow of FIG. 15;

FIG. 17 a workflow for a method to obtain information to control a manufacturing process for a stacked semiconductor device which may be used as an alternative to the FIG. 10 method;

FIG. 18 a workflow for training of a metrology model resulting in a trained metrology model which may be used as an alternative to the trained metrology model of FIG. 14; and

FIG. 19 a workflow for training of a metrology model resulting in a trained metrology model which may be used as an alternative to the trained metrology model of FIG. 14.

### DETAILED DESCRIPTION

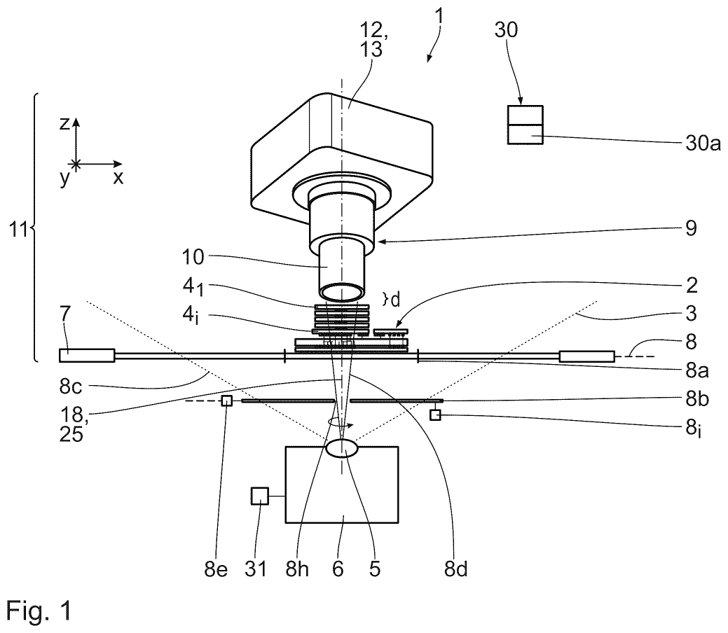

A detection system 1 serves to investigate or inspect an object or sample 2 which is illuminated by X-rays 3. The detection system 1 in particular serves to investigate the quality of packaging, i.e. the quality of mechanical and electrical bonding of electronic components in particular on a chip with micro-and/or nanostructures. Such electronic components often are arranged in a layered, three-dimensional (3D) structure. In FIG. 1, several layers 4ᵢ (i=1 . . . 3, 5, 7, 10 or more) are shown. Sample details to be investigated include interconnects between tagged layers of the sample 2. Such interconnects further are discussed below.

The sample 2 may be a commercially available multi-chiplet SoC (system on chip).

To facilitate the further description, a Cartesian x-y-z-coordinate system is used hereinafter. In FIG. 1, the x-direction points to the right, the y-direction is perpendicular to the drawing plane and points away from the viewer and the z-direction points upwards.

The layers 4ᵢ are stacked in the z-direction.

The X-rays 3 are emitted from a source region 5 of an X-ray source 6. The X-rays 3 are emitted within an emission cone in which the object 2 is arranged. A typical cone angle of such emission cone is in the range between 90 deg and 175 deg and can be 170 deg. A spot size of the source region 5 can be in the range between 1 μl and 100 μm, depending on the type of the light source 6. A continuous power of the light source 6 can be in the range between 1 W and 200 W and can be, again depending on the type of the light source, 20 W or 50 W.

The X-ray source 6 can be from the type of an open transmissive source or of a liquid metal jet source. An example for an open transmissive X-ray source is a source from the product line “TCHE+” offered from X-RAY WorX GmbH, Germany. An example for a liquid metal jet source is the source “metal jet D2+70kV” offered by Excillum AB.

The object 2 is held by an object mount 7 defining an object plane 8. The object 2 is arranged with respect to the x-y-dimensions within an object field 8a. The object mount 7 is capable to mount objects 2 having a diameter of up to 300 mm or larger.

The object mount 7 can be embodied as a ring mount to have no additional mount material between a used light path of the X-rays 3 and the object 2. Alternatively, the object mount 7 can include a thin organic tray or a multitude of such trays. Such organic tray functions to minimize an absorption of the used X-rays 3. Alternatively, an aluminum and/or glass tray with an appropriate dopant can be used as part of the object mount 7 to filter a low, unwanted energy part of the spectrum of the X-rays 3.

X-ray energies below 10 keV or 15 keV are filtered via a respective object mount side filter. A typical thickness of the organic tray/the aluminum and/or glass tray in a respective embodiment of the object mount 7 can be in the range between 1 mm and 5 mm.

The glass tray can contain appropriate amounts of dopant materials such as Pb, B, As, Bi, Cd, Co, U in particular to optimize the filtering of low energy X-rays.

Between the source region 5 and the object mount 7, a shield stop 8b is arranged in an arrangement plane. The shield stop 8b is arranged in a general light path 8c of the X-rays 3 and serves to select the used light path 8d within the total light path 8c defined by the emission cone of the light source 6. In particular, the shield stop 8b protects uninspected regions of the object 2 from X-ray exposure. The shield stop 8b has a stop opening, which also is referred to as a shield stop aperture. Through the shield stop aperture, the usable light path 8d propagates, which in the further, downward beam path impinges on the object 2.

The shield stop aperture is transmissive for the X-rays 3, which is used to image the object 2. Such shield stop aperture can be circular, can be a square aperture or can be rectangular. Other boundary contours of the shield stop aperture are possible, e.g. a hexagonal contour.

The shield stop 8b is movable via a shield stop displacement drive 8e along at least one stop displacement direction x/y in the arrangement plane of the shield stop 8b.

Such movement of the shield stop 8b executed via the shield stop displacement drive 8e can be a linear displacement along at least one linear displacement direction, e.g. along x/y. Alternatively and depending on the embodiment of the shield stop displacement drive 8g, the movability of the shield stop 8b can be along two displacement directions, e.g. x and y, spanning up the arrangement plane of the shield stop. In an alternative or additional embodiment of the shield stop displacement drive 8e, the shield stop 8b can be movable along at least one curved direction and in particular can be movable along at least one circular direction.

The shield stop 8b can be configured such that the shield stop aperture is variable in size. In particular, the shield stop 8b can be configured as an iris stop with variable size of the stop opening. Such stop opening size/shape variation can be effected by a respective shield stop aperture drive (not shown).

The shield stop aperture can be equipped with a filter. Such filter has the function to filter out the low energy part of the x-ray spectrum coming from the source 6.

The detection system 1 can include a shield stop exchange mount 8f, which is indicated schematically in FIG. 1. Such shield stop exchange mount 8i has the function to exchange between different field stops 8b, in particular to exchange between shield stops 8b with different shield stop apertures and/or to replace a shield stop 8b after its nominal time of use.

The material of the shield stop 8b can be from highly absorptive material, e.g. lead, tungsten alloys. A z thickness of the shield stop 8b is in the range between 100 μm and 1 mm.

The object 2 is imaged via an imaging optical arrangement 9 including an imaging optics 10 being embodied as a microscope objective. The imaging optical arrangement 9 is part of a detection assembly 11, which also includes the object mount 7 and a detection array 12 held within a detection housing 13. The detection array 12 can be a CCD or a CMOS array. The detection array 12 can be configured as a flat panel detector. The detection array 12 can have a minimum image read out time according to 10 frames per second (fps). Such image read out time can be smaller to achieve a higher fps value, in particular more than 10 fps, more than 25 fps and more than 50 fps. As a rule, the image read out time is larger than 5 ms.

The detection assembly 11 has a large field of view (FOV). The FOV depends strongly on the magnification of the used microobjective and can span a range from 70 mm for a 0.4× objective down to 0.7 mm for a 40× objective. Of course, the FOV depends on the size of the detection array 12.

The imaging optical arrangement 9 can be arranged such that the imaging optics 10 is exchangeable, in particular to switch between different magnification scales.

During a respective imaging measurement, the detection array 12, the imaging optics 10 and the object mount 7 are arranged in a fixed spatial relationship to each other. This component group 7, 10 and 12 is moved relative to the X-ray source 6, as is described further down below. For imaging/adjustment purposes, the detection array 12, the imaging optics 10 and the object mount 7 can be adjustable to each other in particular in the z-direction.

A typical distance d between the imaging optics 10 and the object 2 is in the range of 1 mm.

A typical minimum distance between the object plane 8, i.e. the arrangement plane of the object mount 7, and the arrangement plane of the shield stop 8b is 1 mm. A typical minimum distance between the source region 5 of the X-ray source 6 and the shield stop 8b is in the range of 1 mm.

The resulting low distance between the source region 5 and the object 2 results in a maximum throughput of the used light path 8e. Further, such minimum distance between the object 2 and the imaging optics 10 results in a maximum resolution of the object imaging.

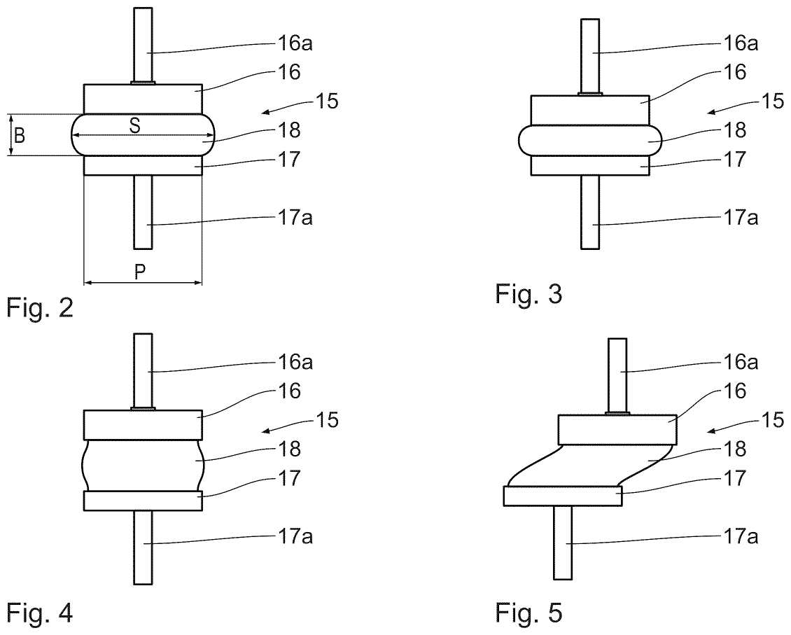

FIG. 2 shows a side view of an interconnection 15 which serves to electrically interconnect chiplets located in adjacent layers 4ᵢ, 4ᵢ₊₁ of the sample 2. Such interconnection 15 also is referred to as an interconnect.

The interconnection 15 has two contact pads 16, 17 which are electrically connected to the respective chiplets via contact lines 16a, 17a. Between the two contact pads 16, 17 a solder mass 18 is located, which serves to electrically interconnect the two contact pads 16 and 17. The contact pads 16, 17 are made of Cu. The solder mass 18 is mainly made of Sn.

The interconnection 15 may be embodied as a Sn-based soldering or as a Cu—Cu-interconnect. In case of a Cu—Cu-interconnect, the solder mass is omitted.

FIG. 2 shows the interconnect 15 in a nominal, desired position, where a distance B between the two contact pads 16, 17, which also is known as solder height or bond line, a width or diameter S of the solder mass 18, which also is known as solder extrusion, and a lateral offset P between the two contact pads 16, 17 have nominal values which are shown in FIG. 2. An offset P is 0 in case the diameters of the two contact pads 16, 17 are perfectly aligned as shown in FIG. 2. B, S and P are examples for metrology parameters to be retrieved.

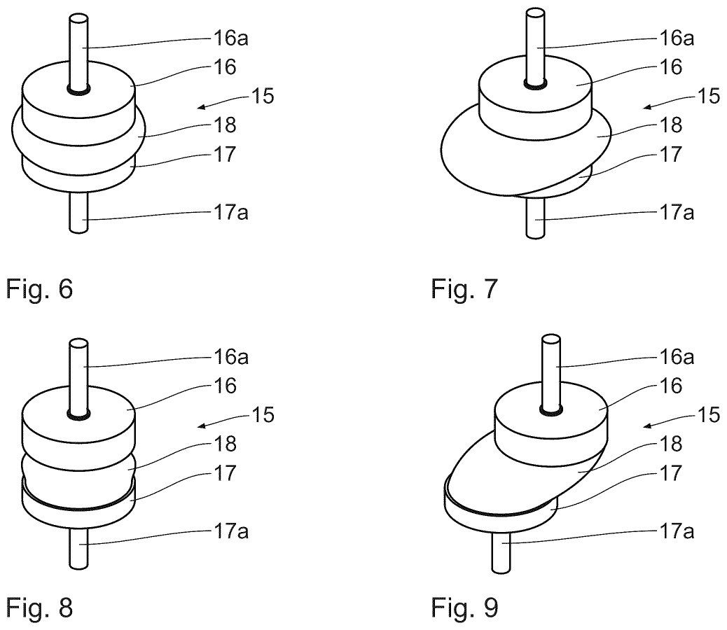

FIG. 6 shows the interconnect 15 in the nominal position of FIG. 2 in a perspective view. In this nominal position, the solder extrusion S is slightly larger than the contact pad diameter of the contact pads 16, 17.

FIGS. 3 and 7 show another relative position of the components 16, 17, 18 of the interconnect 15, wherein the bond line B is smaller than the nominal value shown in FIG. 2, resulting in a squeezed solder mass 18. Such squeezing results in a larger and to a certain extent intolerable overlap of the solder mass 18 over the diameter of the contact pads 16, 17.

Via a method to obtain information to control a manufacturing process for the object 2 including analysis of such interconnects 15, such undesirable relative positioning according to FIGS. 3 and 7 can be detected and the manufacturing process can be realigned accordingly to avoid such undesired relative arrangement.

Further relative position of the components 16 to 18 of the interconnect 15 which deviate from those of FIGS. 2 and 3 are shown in FIGS. 4 and 8 and further in FIGS. 5 and 9.

FIGS. 4 and 8 show a situation, wherein the bond line B is larger than the nominal value shown in FIG. 2. This results in a stretched solder mass 18 and in consequence results in a diameter of the solder mass 18 which is more or less the same as the diameter of the contact pads 16, 17. Such stretched solder mass 18 to a certain extent also is undesirable.

FIGS. 5 and 9 show a relative position of the components 16 to 18, wherein the two contact pads 16 and 17 have a large offset in the xy plain. Such offset is in the relative position of FIGS. 5 and 9 50% of the contact pad diameter. Such large offset also is to a certain extent undesirable.

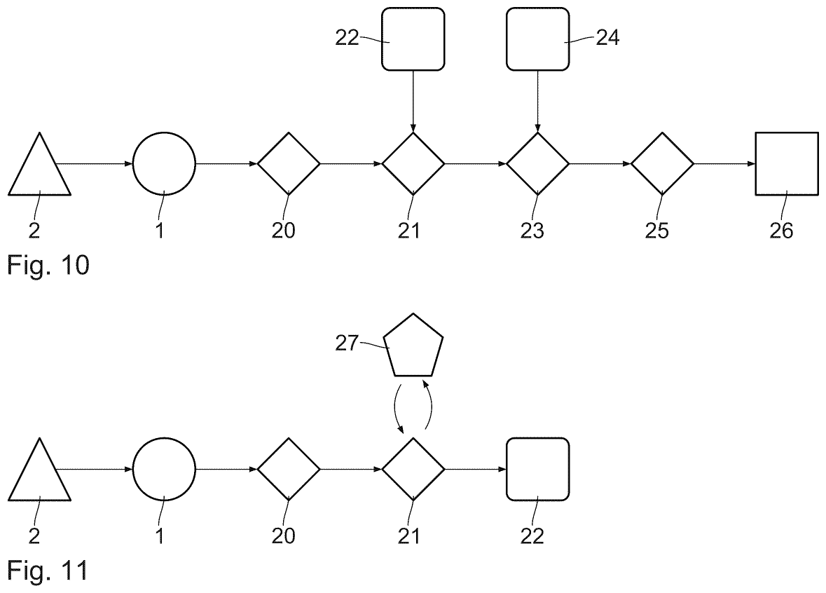

As far as they are undesirable, the relative positions shown in FIGS. 4 and 5 also can be detected and ruled out via the method to obtain information to control the manufacturing process which is now described in greater detail with help of FIGS. 10 to 18.

Those FIGS. 10 to 18 show workflows, i.e. show certain methods or show certain sub-routines which result in models which are usable for the main workflows.

A rectangular or square shown in these FIGS. 10 to 18 is attributed to metrology data. A rectangular or square with spherical corners is attributed to data from a machine learning model, i.e. represents the trained machine learning model, including the learnable/learned coefficients and the software code to apply it. A circle is attributed to an application of a measurement process on the sample, e.g. an incoming edge or a preceding node, resulting in data, e.g. an outgoing edge. Such circle may be attributed to data obtained from the detection system 1 which may be embodied as an X-ray scanner. A rhombus is attributed to data from software components used within the method. In particular, such rhombus may be attributed to a piece of software ingesting data (inflowing edge) producing other kinds of data (outgoing edge). A triangle is attributed to data from a physical or CAD sample, i.e. the sample or the object 2. A pentagon is attributed to inputs which may result from a manual or semi-automatic or even from an automatic task. An arrow is attributed to a data flow. A double arrow with a broken line is attributed to matched data, i.e. different measurements and/or processing of the same physical or virtual sample.

FIG. 10 shows a workflow of an embodiment or the method to obtain information to control the manufacturing process for the stacked semiconductor device, i.e. the object 2.

The method according to FIG. 10 starts from data of a previously unknown physical sample, i.e. the object 2. This sample data is presented to the detection system 1 which is operated in a fast mode, in which rough X-ray imaging data are obtained. In this fast mode, the detection system 1 operates with a scan resolution which is at least ten times smaller than a nominal scan resolution, which is achievable via the detection system 1. In particular, in the fast mode, sample data are produced via a projection scheme with a lower signal quality. A limited view of the sample may be obtained during the fast mode and/or data having more noise. The fast mode data may have different types of artifacts in a finally reconstructed sample volume. In general, such resolution difference between the fast mode and a nominal, accurate mode of the detection system 1 may be larger than 10 and may be 20 or 50 or even larger. In general, such ratio is smaller than 103.

During the accurate mode, a dense scanning angle is used and a full 180° angular coverage of the X-ray general light path. In the fast mode, also a dense scanning angle may be used, but with a limited 100° angular coverage. In that sense, the fast mode may be a sub-set of the accurate mode of the detection system 1.

Projection stack data obtained from the detection system 1 in the FIG. 10 workflow are input for a software algorithm in which a sample volume of the sample 2 analysed via the detection system 1 is reconstructed. Such software algorithm 20 also is referred to as a volume reconstructor. Such software algorithm 20 is an example for a method wherein sample detail information of sample details is gathered which is vital for the manufacturing process from the X-ray imaging data of the detection system 1.

With the volume reconstructor 20 an aerial image of the volume analysed via the detection system 1 is generated.

This data volume generated by the volume reconstructor 20 then is input for a further software algorithm 21 in which an identification and an extraction of at least Region of Interest is performed. Via this ROI identification and extraction 21, Regions of Interest (ROIs) within the sample volume reconstructed via the volume reconstructor 20 are identified and extracted from the volume data. Such Regions of Interest in particular include the interconnect 15 mentioned above.

Such ROI identification and extraction 21 is performed via a pre-trained ROI identification model 22 which gives further data input to the ROI identification and extraction 21 to enable this software algorithm to perform its task. The ROI identification and extraction 21 outputs data referring to multiple identified and extracted ROIs which also are referred to as sub-volumes of the full volume output via the volume reconstructor 20. Such sub-volume data is input for a further software algorithm 23 which performs an artifact correction. Such artifact correction 23 is part of an extraction of metrology data from the ROIs identified via the ROI identification and extraction 21. Input to the artifact correction 23 further is data obtained from a pre-trained volume correction model 24 which helps the artifact correction 23 to perform its task. Output data from the artifact correction 23 is input for further software algorithm 25 which also is referred to as metrology. During the metrology 25, metrology parameters, e.g. the parameters B, S, and P explained above with respect to FIGS. 2 to 9, are obtained from the data resulting from the artifact correction 23. Such metrology parameters are output from the metrology 25 to a database 26 storing actionable information for the process control of the manufacturing process for the stacked semiconductor, in particular to correct process steps in case the obtained metrology parameters are beyond tolerance ranges.

The ROI identification and extraction software algorithm 21 processes the full reconstructed volume and generates the set of sub-volumes of relevant ROIs containing one or multiple interconnects. Its purpose is both to reduce the processing load of and the variability of the sub-volumes as seen by the downstream stages. So no model capacity has to be utilized to learn to reliably correct non-IC structures which are not relevant for the final metrology parameters. In order to achieve good performance (both in terms of accuracy/recall and fit of the sub-volume extent to the contained structures), a dedicated pre-trained ROI identification model is utilized.

The artifact corrections of the algorithm 23 processes the set of sub-volumes with reduced image quality and generates a corresponding set with improved image quality. Its purpose is to reduce the volume artifacts (resulting from the fast mode scanning protocol of the X-ray inspection tool) and to ultimately improve the accuracy of the downstream metrology parameters. In order to achieve a good performance, a dedicated pre-trained artifact correction model is utilized. An example for such an artifact correction is given in Jin et al., IEEE Transactions on Image Processing, vol. 26, no. 9, September 2017, 4509 to 4522.

The ROI identification model 22 is trained during a “ramp up phase” whenever a new family of interconnects 15 has to be routinely inspected and can afterwards be applied for regular process control.

FIG. 11 shows a workflow to obtain the trained ROI detection model 22 which is used in the FIG. 10 workflow. The FIG. 11 workflow again starts with data from the object 2 acquired via the detection system 1 in the fast mode. Also in the FIG. 11 workflow, the volume reconstructor software algorithm 20 is used and its output data are processed in the ROI detection and extraction software algorithm. Data from this ROI detection and extraction 21 are output to a qualifying interactive sample annotation 27, where candidate ROIs, which are the result of the ROI detection and extraction 21, undergo a qualification process to determine whether these ROIs indeed are helpful in the further course of the analysis of the respective sample details.

Instead of the interactive sample annotation 27, a classical algorithm may be used. During such classical algorithm, bright regions in the image may be identified and the environment of such bright regions is cut away. Such classical algorithm may have limitations regarding quality and generalisability. The interactive sample annotation 27 may be done as a preparation step and may be done manually.

Candidate ROIs alternatively may be known a priori, in particular from CAD sample data.

Respectively qualified ROIs are then again input to the ROI detection and extraction 21 as part of a machine learning process. An interaction between the ROI detection and extraction 21 on the one hand and the interactive sample annotation 27 on the other, may be supported by the feeding of a neuronal network and/or may be supported by a Hough Forest (see citation below). From this qualification interaction, the ROI detection and extraction software algorithm 21 learns to handle new kinds of volume data, which are output from the volume reconstructor 20, and to decide where in these new volume data ROIs are found to be helpful for gathering sample detail information of sample details which are vital for the manufacturing process. The correspondingly trained ROI detection and extraction software algorithm 21 then provides output data to the trained ROI detection model 22 which then is ready for interaction within the FIG. 10 workflow.

In the workflow to train the specific ROI identification model 22 being summarized in FIG. 11, first, a representative set of physical samples is imaged with the scanner of the X-ray inspection tool and subsequently the full volumes are reconstructed. Then, the model is trained interactively (e.g. using a Hough Forest Detector) with feedback from the user. Such interactive training, in particular with a Hough Forest Detector, is described in US 2022/0044949 A1 and in Gall et al., IEEE Transactions on Pattern Analysis and Machine Intelligence, vol. 33, no. 11, November 2011, DOI: 10.1109/TPAMI.2011.70, https://ieeexplore.ieee.org/document/5740927.

The training algorithm presents the user a (sub-) volume and asks to either annotate the to be extracted interconnects or to evaluate the proposals of the current version of the model. The user inputs are subsequently utilized to generate an updated, improved version of the model. The process is repeated until the user is satisfied with the model's performance. The proposed, interactive annotation approach considerably reduces the manual labelling effort as compared to Deep Learning-based approaches. Furthermore, the computational cost of the proposed lightweight model is much lower as compared to state-of-the-art Deep Learning-based object detectors.

Via the ROI detection and extraction software algorithm 21 and the interactive sample annotation 27, an ROI identification training process is performed which is based on a starting set of several interactively labelled ROIs. Labelling and training may be performed in parallel.

As an alternative to the extraction software algorithm 21 and to the interactive sample annotation 27, with the output of the volume reconstructor software algorithm 20, a machine learning model training software algorithm may be fed. Such machine learning model training may have further input from previously annotated samples and/or region of interest labels. Such input may be given during a machine learning model training being embodied as a deep learning model.

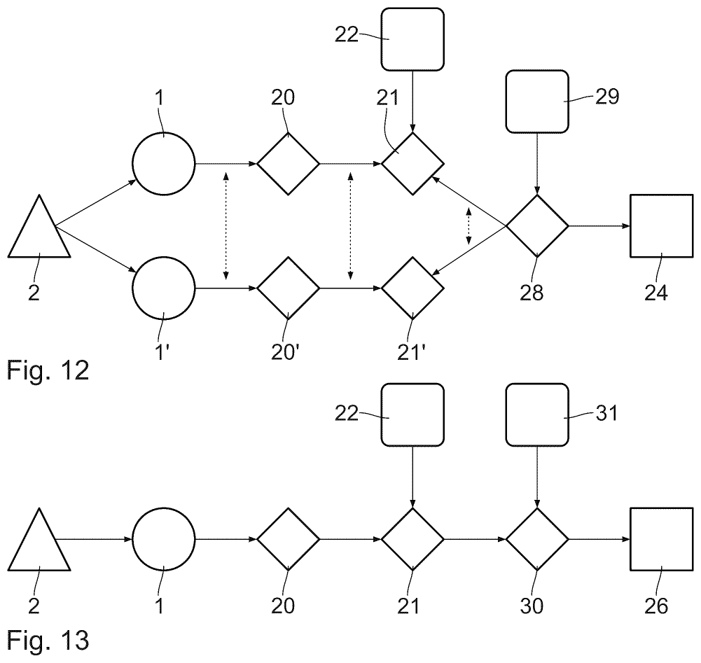

FIG. 12 shows a workflow for training of the volume correction model 24 which also is used within the FIG. 10 workflow.

The FIG. 12 workflow again starts from data from the object 2.

From the sample 2, sample detail information of sample details is gathered which is vital for the manufacturing process. In the FIG. 12 workflow, such sample detail information gathering is performed in parallel. An upper line in FIG. 12 shows such sample detail information gathering via the detection system 1 operating in the fast mode. Including the ROI identification and extraction 21, this upper line workflow part of FIG. 12 corresponds to that of the workflows of FIGS. 10 and 11.

Further, in a lower line of the FIG. 12 workflow, again, sample data is obtained via the detection system 1 now operating in the accurate mode. To distinguish the accurate mode from fast mode in FIG. 12, the detection system and the respective workflow/method steps operating in the accurate mode in FIG. 12 and also in the further figures is denoted with a “′”, e.g. 1′.

Output data from the detection system 1′ in the accurate mode, i.e. imaging data from the sample 2 scanned with the nominal resolution of the detection system then is input to the volume reconstructor software algorithm 20 which processes these accurate imaging data. The imaging data from the fast mode 1 on the one hand and from the accurate mode l′ on the other, match in so far as they only differ in resolution and/or may differ in the kind of present artifacts. Also, the output data of the volume reconstructors 20 processing fast mode data on the one hand and the accurate mode data on the other, match insofar as their input only differs in resolution and/or in the kind of the present artifacts.

The output of the volume reconstructor 20 processing the accurate data then is input to the ROI identification and extraction software algorithm 21′.

The ROI identification and extraction 21 working with the fast mode data get further input from the trained ROI identification model 22 resulting from the training method discussed above with respect to FIG. 11.

Output from the fast mode ROI identification and extraction 21, which uses numerical values obtained from the trained ROI identification model 22, then is compared to the matching output from the accurate mode ROI identification and extraction 21′ in a machine learning model training software algorithm 28 in the FIG. 12 workflow. Such machine learning (ML) model training 28 may have further input from a generic model 29 to be fine-tuned.

Such generic model 29 is not adapted to a specific shape and size of an interconnect of the sample. During the fine-tuning of the generic model 29, a training is started using numerical values which are the result of a preparational training instead of using random values.

Such fine-tuning results in an improvement of the quality of the extracted metrology data.

The correspondingly trained ML model training software algorithm 28 then outputs the trained volume correction model 24, which then can be used within the FIG. 10 workflow.

The volume correction model 24 is trained during a “ramp-up phase” whenever a new family of interconnects has to be routinely inspected and can afterwards be applied for regular process control.

In the workflow to train a specific volume correction model, first, a representative set of physical samples is imaged with the scanner of the X-ray inspection tool in two image acquisition modes: a fast mode that achieves the desired throughput (but maybe not the image quality) and is used during regular process control; and an accurate mode that achieves the desired image quality (but maybe not the throughput). Alternatively, the fast mode can be emulated from the accurate mode data by discarding or corrupting measurement data. As further option, the training data can be acquired and/or emulated with a dedicated device other than the regular detection system 1. Next, each of the matched projection stacks is reconstructed. The following ROI identification stage extracts the individual interconnects and results in a matched data set of sub-volumes (input: fast mode; ground truth: accurate mode). The data set is subsequently used to train the volume correction model in supervised fashion. The underlying architecture might be a 2.5-D or 3-D fully convolutional architecture or a variant of the “Transformer” family.

Details of a potential model and training procedure could be as follows: The volume correction model ingests (sub-) volumes of interest and emits corresponding volumes of identical or slightly reduced size. The architecture can be a 3-D fully convolutional network, comprising at least 3-D convolution blocks and down-sampling and up-sampling blocks (e.g. 3-D UNets). Alternatively, if memory restrictions do not permit training with full (sub-) volumes of interest, 2.5-D models can be used: The volume is sliced in one dimension (typically the z-dimension perpendicular to the scanning directions), extracting multiple thin z-regions around the respective central planes. Subsequently, a similar, fully convolutional network (convolutional in x-y-directions, fully connected in the sliced z-direction) architecture is used as model. For both approaches, the network is trained in supervised fashion with a set of pairs of corrupted and uncorrupted volumes, using standard machine learning algorithms. As loss function, an image similarity metric can be used, e.g. pixel based-metrics such as L2-norms.

The volume correction model 24 may be based on a 2.5-D UNet architecture.

FIG. 13 shows another embodiment of a workflow to obtain information in the form of metrology parameters to control the manufacturing process for the stepped semiconductor device, i.e. the object 2. The FIG. 13 workflow may be used as an alternative to the FIG. 10 workflow. The FIG. 13 workflow hereinafter only is discussed where it differs from the FIG. 10 workflow.

Output data from the ROI identification and extraction 21 is in the FIG. 13 workflow directly input to a machine learning based metrology software algorithm 30 which in the FIG. 13 workflow is used instead of the artifact correction 23 and the metrology software algorithm 25 used in the FIG. 10 workflow.

In the metrology software algorithm 30 of the FIG. 13 workflow, metrology data is extracted from the identified ROIs by processing data with the additional support of a trained metrology model 31. Such trained metrology model 31 is obtained from a workflow which hereinafter is described. In the FIG. 13 workflow, the metrology software algorithm 30 outputs the metrology parameters, i.e. the parameters B, S, and P, again to the data base 26.

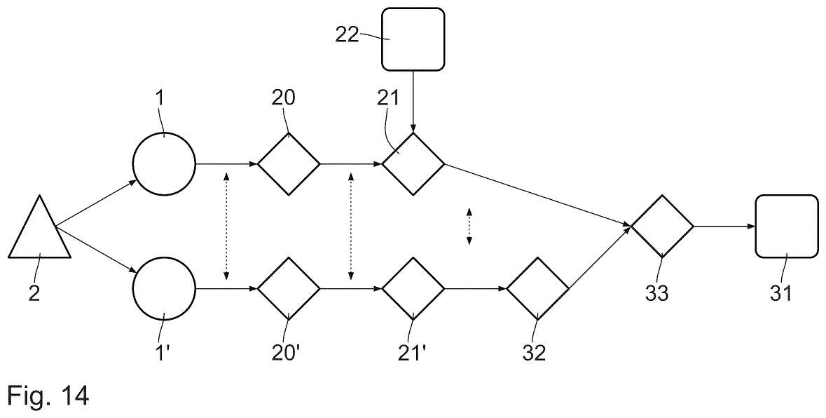

FIG. 14 shows a workflow to obtain the trained metrology model 31. This FIG. 14 workflow hereinafter is discussed only where it deviates from the FIG. 12 workflow resulting in the trained volume correction model 24.

In the FIG. 14 workflow, the ROIs obtained from the ROI identification and extraction 21′ processing the data from the accurate mode is output to a metrology software algorithm 32 extracting the metrology parameters from these accurate ROIs. The metrology software algorithm 32 may be identical to the algorithm 25 described above with reference to FIG. 10.

The extracted metrology parameters are output from the metrology software algorithm 32 to a machine learning model training software algorithm 33. In this machine learning model training software algorithm 33, the accurate metrology parameters output from the metrology's software algorithm 32 are compared with matching data from ROIs which are output from the ROI identification and extraction software algorithm 21, which uses the fast mode data and further is supported via data from the trained ROI identification model 22. In the FIG. 14 workflow, the metrology on the accurate data serving as input for the machine learning model training software algorithm 33 replaces the artifact correction 23, the pre-trained volume correction model 24 and the metrology 25 of the FIG. 10 workflow.

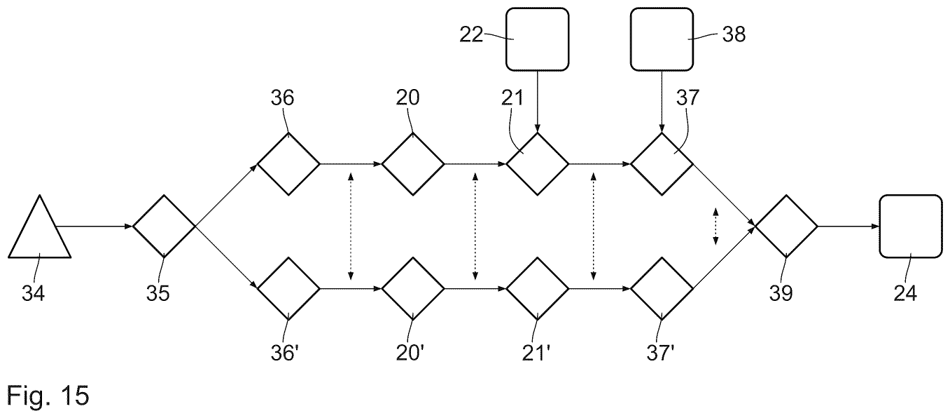

FIG. 15 shows an alternative workflow to obtain the trained volume correction model 24. Consequently, the FIG. 15 workflow may be used as an alternative for the FIG. 12 workflow. Details of the FIG. 15 workflow hereinafter are discussed only where they deviate from the FIG. 12 workflow.

As input for the FIG. 15 workflow, no real sample data is used but data obtained from CAD sample model 34. The respective sample model data may result from a CAD model of the object 2, and in particular of sample details as the interconnects 15. Such sample model data is input for a CAD deformation software algorithm 35, which produces variations of CAD data with high resolution, which then are input for detection system emulations 36, 36′, emulating the fast mode detection on the one hand and the accurate mode detection on the other. Those detection emulations 36, 36′ work with the same set of varied CAD data which are the output of the CAD deformation of the algorithm 35, but emulate the detection with different resolutions as discussed above with respect to the fast mode/accurate mode detection system 1, 1′.

With the FIG. 15 workflow, sample data is provided via CAD data of the sample and not via real physical sample data.

In the FIG. 15 workflow, output from the ROI identification and extraction software algorithms 21, 21′ working with the fast data on the one hand and with the accurate data on the other, are output to respective domain transfer software algorithms 37, 37′. Such domain transfer software algorithm 37, 37′ may also be omitted in the FIG. 15 workflow.

The fast mode data domain transfer software algorithm 37 further is supported via input of a trained domain adaption model 38, which is obtained via a workflow which is discussed hereinafter.

Matched output data from the domain transfer software algorithms 37, 37′ are set to a machine learning model training software algorithm 39. Goal of this training, again, is to identify sample domains which are obtained via the fast mode process in a quality as such data would have been obtained in the accurate mode. Output of the machine learning model training 39 is the trained volume correction model 24 which then may be used in the FIG. 2 workflow as input for the artifact correction software algorithm 23. By use of the domain transfer software algorithm 37, 37′, the trained volume correction model 24 works also with measured sample data irrespective of the fact that during the training mode the trained volume correction model 24 only is input with simulated data lacking certain characteristics of measured data. The domain transfer software algorithm 37, 37′ adds respective characteristics. It has to be emphasized that the FIG. 15 workflow does not require identical correspondence between measured sample data and CAD sample data.

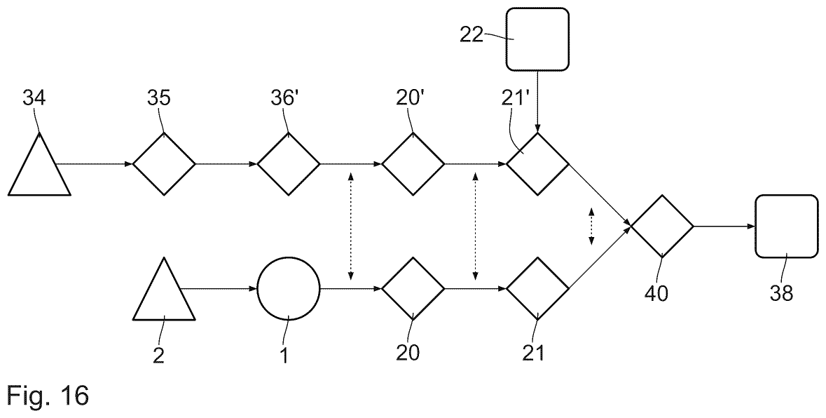

FIG. 16 shows a workflow to obtain the trained domain adaption model 38 to be used in FIG. 15 workflow.

In this FIG. 16 workflow, in a first route shown in the upper line of the FIG. 16 workflow, data from the sample model 34 are processed. Further, in a second route, shown in the lower line of the FIG. 16 workflow, data stemming from the real object 2 is processed in the fast mode as shown e.g. in the upper line of the FIG. 12 workflow. The upper line of the FIG. 16 workflow corresponds to the lower line of the FIG. 15 workflow, i.e. corresponds to a processing of sample model data with an accurate mode detection system emulation. The full volume data output from the volume reconstructor software algorithm 20′ working with the sample model data is output to the ROI identification and extraction software algorithm 21′, which further is supported via the trained ROI identification model 22 discussed above. Output from this accurate ROI identification and extraction software algorithm 21′ then together with output from the fast mode data processed in the ROI identification and extraction software algorithm 21 into a machine learning model training 40. Different to the machine learning model training 29 in the FIG. 12 workflow, these CAD/real sample input data from the two routes are no matching data, i.e. do not stem from a common data source. The training process of the domain transfer model might, e.g., be based on the GAN setting utilizing a discriminator attempting to discern real physical inputs from transformed simulated CAD inputs.

Output of the machine learning model training 40 is the trained domain adaption model 38 which then is used in the FIG. 15 workflow.

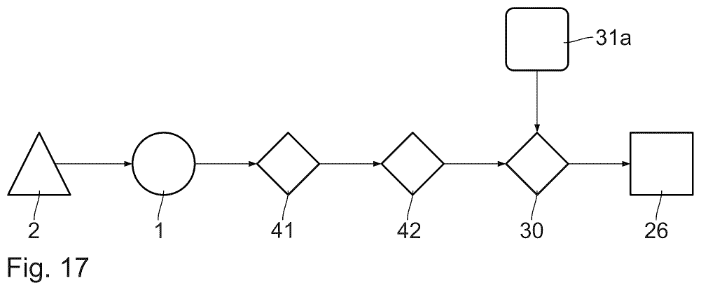

FIG. 17 shows an alternative workflow to obtain the information to control the manufacturing process from the stacked semiconductor device, which may be used as a further alternative to the workflows of FIGS. 10 and 13. The FIG. 17 workflow hereinafter is discussed only in details which deviate from the FIGS. 10 and 13 workflows.

In the FIG. 17 workflow, the imaging data output of the fast mode detection system 1 is fed into a contact identification software algorithm 41 which identifies xyz coordinates of potential contact elements, in particular of interconnects like the interconnect 15 discussed above, which are located in at least a part of the sample 2. Such contact identification includes coordinate information of at least two adjacent semiconductor layers of the object 2.

Output of the contact identification 41 are center coordinates of the respective interconnects 15. This output is fed into a ROI extraction in projections software algorithm 42. Output of the ROI extraction in projections software algorithm 42 are no (volumetric) Regions of Interest but cropped projection stacks including the interconnect coordinates to be further investigated. The output of the ROI extraction in projections algorithm 42 then is fed to the metrology software algorithm 30 which is supported via a trained metrology model 31a which is somewhat comparable to the discussion above with respect to the FIG. 13 workflow. Input for the trained metrology model 31a are crops of measuring data from different directions. In the FIG. 17 workflow, the metrology parameters are directly obtained on measurement data without a volume reconstruction. For each of the potential contact center coordinates and for each of the projection images of the fast mode detection system 1, an ROI is cropped around the center coordinate, is re-projected on the detector of the detection system 1, and subsequently passed to the machine learning based metrology software algorithm 30 to directly infer the metrology parameters, i.e. the parameters B, S, and P, of interest. Re-projection means here to translate an identified potential center of a contact given in Cartesian coordinates xyz via geometric configurations for each of the projections in a pixel coordinate w, h and to further extract it in an area of pixel coordinates.

The center coordinates which are output of the contact identification software algorithm 31a may be generated with different methods as discussed e.g. with respect to the FIG. 10 workflow, or alternatively from a CAD sample layout or from previously inspected samples or from sample periodicity and/or sample layer assumptions.

The input of the metrology software algorithm 30 in the FIG. 17 workflow, i.e. the cropped projection stack, may—for each contact—be only <1% of a full volume which in the alternative workflows discussed here is processed by the volume reconstructor software algorithm 20, 20′.

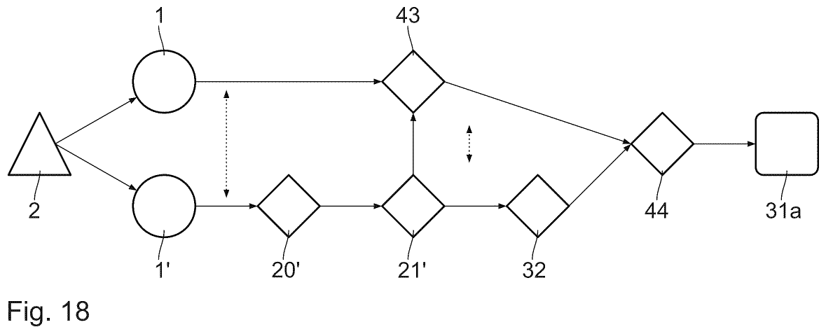

FIG. 18 shows a workflow for obtaining the trained metrology model 31a which may be used as an alternative for the FIG. 14 workflow. The FIG. 18 workflow hereinafter is discussed only where it deviates from the FIG. 14 workflow.

In the FIG. 18 workflow, with respect to the fast mode data processing, the volume reconstructor software algorithm is omitted. Instead, projection data from the fast mode detection system 1 directly is fed into an ROI extraction in projections software algorithm 43 which works similar to the ROI extraction in projections software algorithm 42 of the FIG. 17 workflow.

The ROI extraction in projections software algorithm 43 additionally gets center coordinate data from the ROI identification and extraction software algorithm 21′ working with the accurate mode data.

Output of the ROI extraction in projections software algorithm 43 are cropped projection stack data comparable to those of the FIG. 17 algorithm. These cropped projection stacked data of the

ROI extraction in projections software algorithm 43 are fed together with the metrology parameters obtained from the metrology software algorithm from the accurate data into a machine learning model training software algorithm 44. The result of this machine learning model training software algorithm is the trained metrology model 31a. Here, the training of the metrology model directly operates on measurement data in the fast mode without volume reconstructor.

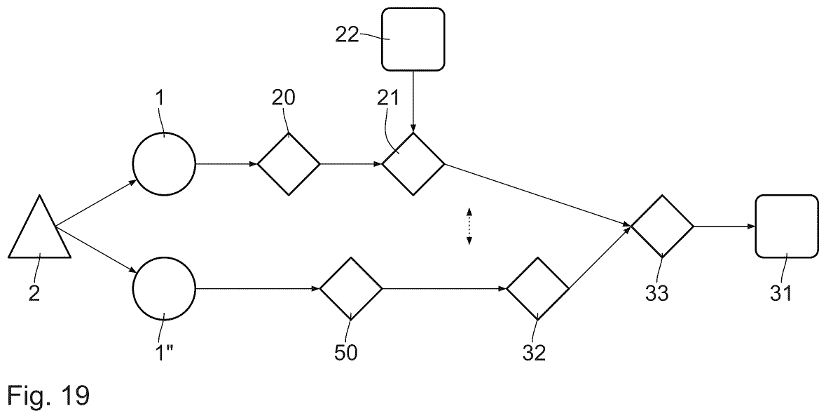

FIG. 19 shows a workflow to obtain the trained metrology model 31 alternatively to the workflow according to FIG. 14. Details of the FIG. 19 workflow hereinafter are discussed only where they deviate from the workflows described above and in particular where they deviate from the FIG. 14 workflow.

As an alternative to the accurate mode lower line of the workflows according to FIGS. 12 and 14, measurement data are gathered via an alternative metrology device 1″ and are post processed via a post processing software algorithm 50. Resulting multiple ROIs are then fed into the metrology software algorithm 32 which results then, together with results of the ROI identification and extraction software algorithm 21 from the upper fast mode line of the FIG. 19 workflow, are fed to the machine learning model training software algorithm 33.

The label metrology parameters from the reference branch (bottom in FIG. 19) are not required to stem from the same imaging modality as the input branch (top in FIG. 19) in a potentially different acquisition mode. Instead, arbitrary metrology devices that are able to yield the metrology parameters of interest can be used. This includes metrology devices that are not suitable for inline inspection, in particular destructive sample handling. Examples might be FIB-SEM inspection or mechanical slicing plus optical inspection.

There are multiple variants of the above workflow and training procedure:
The processing steps of both branches in the volume correction training (see FIG. 12) do not need to be identical. The accurate mode branch might include alternative or additional processing stages that are computationally too heavy to be applied during regular process control such as advanced reconstruction methods like iterative reconstruction.
Alternatively to training from scratch at “ramp-up phase”, a tool vendor provided model might be used as model initialization to reduce the number of training samples to be acquired or even as final model to entirely spare sample acquisition. A generic model may be fine-tuned in this manner.
Alternatively to using separate volume correction (learnt) and metrology (non-data-driven) stages, a learnt, single step metrology model might directly infer the metrology parameters of interest from the degraded sub-volumes (see FIG. 13). One approach to train the above model is generating the target metrology labels for supervised training via non-data-driven metrology from the matched sub-volumes acquired in accurate mode (see FIG. 13). One variant might be to directly apply the learnt metrology on the full volume, i.e. fuse the ROI identification stage as well, and let the model output the metrology parameters of interest for all interconnects. Incarnations of the model architecture might include deep learning object detectors with a convolutional backbone or Transformer-based architectures.
As a variation to the approach as described in the previous item, the metrology model might directly operate on a suitably selected sub-set of the measurement data without a mandatory reconstruction step (see FIG. 17). For each of the potential contacts, a suitable ROI of each projection is cropped and fed as input to the model. Note that this approach is best applicable when the number of measured projections is highly limited. Further note that the required center coordinates of the contact candidates might be obtained by different methods such as the previously described reconstruction and object detection (see FIG. 10), from previous measurements of the same specimen, from a CAD description of the chiplet design, or from other assumptions such as periodicity and layered structures. A potential way to train such a model is depicted in FIG. 18 and follows similar strategies as other supervised flows for training of the mentioned models.
For the above learnt metrology workflow (see FIG. 13), the label metrology parameters might-as alternative to the accurate mode branch-be obtained by another, potentially destructive modality after acquiring the input sub-volumes in fast mode. Approaches might include “FIB+SEM” or mechanical cutting followed by optical inspection.
Generation of the required training data for the volume correction and the metrology model can also be performed with simulated data instead of experimentally acquired data (see FIG. 15). The starting point is a CAD description of the nominal specification of the novel interconnect family, of which statistical variations in terms of deformation and enhancements such as voids are subsequently generated. Note that the variation of the generated virtual samples is best picked sufficiently rich such that not only samples resembling acceptable interconnects are generated but also samples resembling defective interconnects (as probable to be encountered during process control). The virtual samples are passed to a simulator that emulates the X-ray inspection tool measurements in both accurate mode and fast mode. Emulated measurements are then processed and used for training of the volume correction as for the case of experimental data (compare with FIG. 12).
When training a “metrology” model from CAD description, the metrology parameter labels can alternatively be directly derived from the CAD geometry (instead of from the accurate mode branch). The training pipeline with CAD data might optionally include a learnt “Domain transfer” stage to perform Domain Adaption, details with respect to such Domain Adaption can be found in J. Hoffman et al. “CyCADA: Cycle-Consistent Adversarial Domain Adaptation” (arXiv:1711.03213v3). Its job is to adapt specific characteristics in the simulated sub-volume such that it resembles actual experimental measurements and that ultimately the performance of the trained “volume correction” stage is sufficient on experimental data as well (small “sim2real gap”). Training of the “domain transfer” model requires a set of simulated sub-volumes and a similar, but unmatched set of experimentally acquired sub-volumes, potentially Fast Mode only.
The training pipeline with CAD data might optionally use a combination of simulated CAD data and experimentally acquired data for training in supervised fashion. Variants might include training with a mix of simulated and experimental data (e.g. if a class of data such as defects are underrepresented in the experimental data) or pre-training with a large number of simulated data and subsequent fine-tuning with a deduced number of experimental data (e.g. when acquiring Accurate Mode data is associated with high cost).

In some implementations, the various software algorithms, models, and processes can be implemented using one or more computing devices. Each computing device can include one or more data processors. Each data processor can include one or more processor cores, and each processor core can include logic circuitry for processing data. For example, a data processor can include an arithmetic and logic unit (ALU), a control unit, and various registers. Each data processor can include cache memory. Each data processor can include a system-on-chip (SoC) that includes multiple processor cores, random access memory, graphics processing units, one or more controllers, and one or more communication modules. Each data processor can include millions or billions of transistors.

In some implementations, the program code and associated data for the algorithms and models can be stored in one or more machine-readable storage devices, such as hard drives, magnetic disks, solid state drives, magneto-optical disks, or optical disks. Alternatively or in addition, the program code and data can be encoded on a propagated signal that is an artificially generated signal, e.g., a machine-generated electrical, optical, or electromagnetic signal, that is generated to encode information for transmission to suitable receiver apparatus for execution by a programmable processor. The program code can be written in any form of programming language, including compiled or interpreted languages, and it can be deployed in any form, including as a stand-alone program or as a module, component, subroutine, or other unit suitable for use in a computing environment.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one data processor, at least one data storage system (including volatile and non-volatile memory and/or storage elements), at least one wired or wireless input device or port, and at least one wired or wireless output device or port.

In some implementations, the various drives (e.g., shield stop displacement drive, object displacement drive, shield stope aperture drive) can be controlled by one or more control devices, each control device having one or more drive control units, each drive control unit having electronic circuitry for receiving input signals, such as signals from one or more position sensors, electronic circuitry for processing the input signals and generating control signals, and electronic circuitry for outputting the control signals for controlling the one or more actuators (e.g., motors) of the drives. For example, a control device can include a proportional-integral-derivative (PID) control unit, and/or a digital signal processing (DSP) unit.

In some examples, the algorithms and processes described above can be used to identify a large number of regions of interest on an object, such as a stacked semiconductor device. The number of regions of interest can be in the range of, e.g., tens, hundreds, thousands, or millions, or more. The processes described above provides a way to automate or partially automate the task of identifying the regions of interest from which information useful for controlling the manufacturing process can be obtained.

In some implementations, the metrology data extracted from the identified regions of interest can be used to control the manufacturing process, such as realigning processes for producing interconnects to avoid undesired relative arrangements, e.g., such as those shown in FIGS. 5 and 9. The metrology data can include actionable information for the process control of the manufacturing process for stacked semiconductor devices, in particular to correct process steps in case the obtained metrology parameters are beyond tolerance ranges.

What is claimed is:

1. A method to obtain information to control a manufacturing process for a stacked semiconductor device including several semiconductor layers requiring electrical interconnection, the method including the following steps:
providing sample data of a semiconductor device sample to be inspected,
performing an X-ray imaging scan of the sample and obtaining respective X-ray imaging data,
gathering sample detail information of sample details of the sample which are vital for the manufacturing process from the X-ray imaging data,
identifying multiple regions of interests (ROIs) from the gathered sample detail information by processing data resulting from an ROI identification model, such ROI identification model being previously trained in a machine learning process, and
extracting metrology data from the identified ROIs by processing data resulting from a metrology model, such metrology model being previously trained in a machine learning process.

2. The method according to claim 1 wherein the ROI identification model results from the following method steps:
providing sample data of a semiconductor device sample to be inspected,
performing an X-ray imaging scan of the sample and obtaining respective X-ray imaging data,
gathering sample detail information of sample details of the sample which are vital for the manufacturing process from the X-ray imaging data, and
detecting and extracting the multiple ROIs from the gathered sample detail information by processing data resulting from an ROI identification training process based on a starting set of several interactively labelled ROIs during the machine learning process.

3. The method according to claim 2, wherein the metrology model results from the following method steps:
providing sample data of a semiconductor device sample to be inspected,
gathering sample detail information of sample details of the sample which are vital for the manufacturing process from the X-ray imaging data, such sample detail information gathering being performed in parallel
in an accurate X-ray imaging scan of the sample obtaining respectively accurately X-ray imaging data and
in a fast mode obtaining rough X-ray imaging data,
identifying multiple ROIs in parallel:
from the gathered sample detail information from the accurate X-ray imaging scan and
from the gathered sample detail information from the fast mode using the trained ROI identification model,
performing a metrology over the identified ROIs obtained via the gathered sample detail information from the accurate X-ray imaging scan, the metrology resulting in metrology data, and
obtaining the metrology model via a machine learning training-based comparison between the metrology data and data obtained from the gathering of sample detail information in the fast mode.

4. The method according to claim 1, wherein during the extraction of metrology data an artifact correction step is performed by processing data resulting from a volume correction model, such volume correction model being previously trained in a machine learning process.

5. The method according to claim 4 wherein the volume correction model results from the following method steps:
providing sample data of a semiconductor device sample to be inspected,
gathering sample detail information of sample details of the sample which are vital for the manufacturing process from the X-ray imaging data, such sample detail information gathering being performed in parallel
in an accurate X-ray imaging scan of the sample obtaining respectively accurate X-ray imaging data and
in a fast mode obtaining rough X-ray imaging data,
identifying multiple ROIs in parallel
from the gathered sample detail information from the accurate X-ray imaging scan and
from the gathered sample detail information from the fast mode using the trained ROI identification model, and
obtaining the volume correction model via a machine learning training based comparison between
the ROI identification data from the accurate X-ray imaging scan and
the ROI identification data obtained from the gathering of sample detail information in the fast mode.

6. The method according to claim 1, wherein prior to the machine learning training based comparison, the ROI identification data obtained in parallel in the accurate scan and in the fast mode undergo a domain transfer with input of a pre-trained domain adaption model.

7. The method according to claim 6, wherein the domain adaption model results from the following method steps:
obtaining ROI identification data in parallel via the following routes:
in a first route:
providing a CAD model of a contact arrangement of contacts between adjacent semiconductor layers of the stacked semiconductor device,
deforming the CAD model data obtained in the previous provision step,
emulating an X-ray imaging scan of the deformed CAD data,
identifying multiple ROIs from gathered sample detail information from the emulated X-ray imaging scan using the input of the trained ROI identification model; and
in a second route:
providing sample data of a semiconductor device sample to be inspected,
gathering sample detail information of sample details of the sample in a fast X-ray imaging scan mode obtaining rough X-ray imaging data, and
identifying multiple ROIs from gathered detail information from the fast X-ray imaging scan,
wherein the trained domain adaption model is obtained via a machine learning training based comparison between
the ROI identification data from the emulated X-ray imaging scan and
the ROI identification data obtained from the gathering of sample detail information in the fast mode.

8. The method according to claim 1, wherein the sample detail information is gathered via a volume reconstruction of at least a part of the device sample including at least two adjacent semiconductor layers.

9. The method according to claim 1, wherein the sample detail information is gathered via a contact identification of contact elements located in at least a part of the device sample including at least two adjacent semiconductor layers via the trained metrology model.

10. The method according to claim 9, wherein the metrology model results from the following method steps:
providing sample data of a semiconductor device sample to be inspected,
gathering sample detail information of sample details of the sample which are vital for the manufacturing process from the X-ray imaging data, such sample detail information gathering being performed in parallel
in an accurate X-ray imaging scan of the sample obtaining respectively accurate X-ray imaging data and
in a fast mode, obtaining rough X-ray imaging data,
identifying multiple ROIs in parallel
from the gathered sample detail information from the accurate X-ray imaging scan and
from the gathered sample detail information,
performing a metrology over the identified ROIs obtained via the gathered sample detail information from the accurate X-ray imaging scan, the metrology resulting in metrology data, and
obtaining the metrology model via a machine learning training based comparison between the metrology data and data obtained from the gathering of sample detail information in the fast mode.

11. A detection system for X-ray inspection of an object using the method according to claim 1, the detection system comprising
an X-ray source for generating X-rays,
an imaging optical arrangement to image the object in an object plane illuminated by the X-rays, the imaging optical arrangement comprising an imaging optics to image a transfer field in a field plane into a detection field in a detection plane,
a detection array, arranged at the detection field of the imaging optics, and
an object mount to hold the object to be imaged via the imaging optics.

12. The detection system according to claim 11, wherein the object mount is movable relative to the light source via an object displacement drive along at least one lateral object displacement direction in the object plane.

13. The detection system according to claim 11, further comprising:
a shield stop having a shield stop aperture transmissive for the X-rays used to image the object, the shield stop being arranged in an arrangement plane in a light path of the X-rays between the X-ray source and the object mount, the shield stop being movable via a shield stop displacement drive along at least one stop displacement direction, and
a control device having a drive control unit being in signal connection with the shield stop displacement drive and with the object displacement drive for synchronizing a movement of the shield stop displacement drive and the object displacement drive.

14. The method of claim 2 wherein during the extraction of metrology data an artifact correction step is performed by processing data resulting from a volume correction model, such volume correction model being previously trained in a machine learning process.

15. The method of claim 2 wherein prior to the machine learning training based comparison, the ROI identification data obtained in parallel in the accurate scan and in the fast mode undergo a domain transfer with input of a pre-trained domain adaption model.

16. The method of claim 2 wherein the sample detail information is gathered via a volume reconstruction of at least a part of the device sample including at least two adjacent semiconductor layers.

17. The method of claim 2 wherein the sample detail information is gathered via a contact identification of contact elements located in at least a part of the device sample including at least two adjacent semiconductor layers via the trained metrology model.

18. The detection system of claim 11 wherein the ROI identification model results from the following method steps:
providing sample data of a semiconductor device sample to be inspected,
performing an X-ray imaging scan of the sample and obtaining respective X-ray imaging data,
gathering sample detail information of sample details of the sample which are vital for the manufacturing process from the X-ray imaging data, and
detecting and extracting the multiple ROIs from the gathered sample detail information by processing data resulting from an ROI identification training process based on a starting set of several interactively labelled ROIs during the machine learning process.

19. The detection system of claim 18 wherein the metrology model results from the following method steps:
providing sample data of a semiconductor device sample to be inspected,
gathering sample detail information of sample details of the sample which are vital for the manufacturing process from the X-ray imaging data, such sample detail information gathering being performed in parallel
in an accurate X-ray imaging scan of the sample obtaining respectively accurately X-ray imaging data and
in a fast mode obtaining rough X-ray imaging data,
identifying multiple ROIs in parallel:
from the gathered sample detail information from the accurate X-ray imaging scan and
from the gathered sample detail information from the fast mode using the trained ROI identification model,
performing a metrology over the identified ROIs obtained via the gathered sample detail information from the accurate X-ray imaging scan, the metrology resulting in metrology data, and
obtaining the metrology model via a machine learning training-based comparison between the metrology data and data obtained from the gathering of sample detail information in the fast mode.

20. The detection system of claim 12, further comprising:
a shield stop having a shield stop aperture transmissive for the X-rays used to image the object, the shield stop being arranged in an arrangement plane in a light path of the X-rays between the X-ray source and the object mount, the shield stop being movable via a shield stop displacement drive along at least one stop displacement direction, and
a control device having a drive control unit being in signal connection with the shield stop displacement drive and with the object displacement drive for synchronizing a movement of the shield stop displacement drive and the object displacement drive.
